(19) United States
(12) Patent Application Publication
(10) Pub. No.: US 2015/0037921 A1
(43) Pub. Date: Feb. 5, 2015

(54) METHOD FOR MANUFACTURING ACOUSTIC WAVE DEVICE

(71) Applicant: Murata Manufacturing Co., Ltd., Nagaokakyo-shi (JP)

(72) Inventors: Yohei KONAKA, Nagaokakyo-shi (JP); Seiji KAI, Nagaokakyo-shi (JP)

(21) Appl. No.: 14/341,927

(22) Filed: Jul. 28, 2014

(30) Foreign Application Priority Data
Jul. 31, 2013 (JP) 2013-159042

(51) Int. Cl. B81C 1/00

(52) U.S. Cl. CPC B81C 1/00301; B81C 1/00269; B81C 2203/0145; B81C 2203/0118
USPC 438/51

(57) ABSTRACT

A method for manufacturing acoustic wave devices includes forming power supply lines along boundaries between chip regions on a main surface of a collective substrate on which interdigital transducer (IDT) electrodes and pad electrodes are formed; providing substantially frame-shaped first support members, each including a first opening in which one of the IDT electrodes is located and including first through-holes in a region in which the pad electrodes are formed; providing second support members outside the first support members; providing a lid member including second through-holes at positions overlapping the first through-holes on top surfaces of the first support members; and forming terminal electrodes in the first through-holes and the second through-holes by electroplating. The collective substrate, the first support members, the second support members, and the lid member form enclosed spaces in which the power supply lines are sealed.

### BACKGROUND OF THE INVENTION

1. Field of the Invention

The present invention relates to methods for manufacturing acoustic wave devices.

2. Description of the Related Art

In the field of acoustic wave devices, efforts have been directed toward the development of wafer level packaging (WLP), which allows for a smaller package size (see, for example, Japanese Unexamined Patent Application Publication No. 2012-29134). WLP is a technology where wiring lines are formed on a collective substrate and are sealed with resin before the collective substrate is cut into chip substrates, each of which is packaged.

A process for manufacturing acoustic wave devices by WLP will be described with reference to FIGS. 7A to 7C.

As shown in FIGS. 7A to 7C, interdigital transducer (IDT) electrodes 102 and pad electrodes 103 are first formed on a main surface of a collective substrate 101 including a plurality of chip regions 101a. Power supply lines 104 are formed along the boundaries between the adjacent chip regions 101a. The power supply lines 104 are electrically connected to the pad electrode 103.

As shown in FIGS. 7B and 7C, substantially frame-shaped support members 111 are then formed using a resin material on the main surface of the collective substrate 101. The support members 111 surround the IDT electrodes 102.

As shown in FIG. 7C, a substantially plate-shaped lid member 120 is then bonded to the top surfaces of the support members 111 to form a seal such that the collective substrate 101, the support members 111, and the lid member 120 form hollow spaces.

Through-holes 130b are then formed in the support members 111 and the lid member 120 at positions above the pad electrodes 103.

Terminal electrodes 130 are then formed in the through-holes 130b in the support members 111 and the lid member 120 by electroplating. The terminal electrodes 130 are connected to the pad electrodes 103.

Finally, the collective substrate 101 is divided into chip substrates, each of which is packaged, by cutting the collective substrate 101 along the boundaries between the chip regions 101a using a dicing blade while removing the power supply lines 104. In this manner, acoustic wave devices are completed.

In the above method for manufacturing acoustic wave devices in the related art, the terminal electrodes 130 extending through the support members 111 and the lid member 120 are formed using an electroplating system.

There are several types of electroplating systems, including cup plating systems and rack plating systems. For example, as shown in FIG. 8A, a cup plating system 150 includes a plating cell 151 filled with a plating solution 153 containing a metal such as nickel and a collective substrate rest 152 disposed around a top opening of the plating cell 151. An anode (positive electrode) 154, serving as one of the electroplating electrodes, is disposed in the plating cell 151. The collective substrate rest 152 is composed of a cathode (negative electrode) 156 and a gasket 155.

In the electroplating system 150 shown in FIG. 8B, the collective substrate 101 is placed on the collective substrate rest 152 and is brought into contact with the plating solution 153 in the plating cell 151, with the lid member 120 facing downward. In this state, the anode 154 and the cathode 156 are supplied with current to grow a coating on the surfaces of the pad electrodes 103 exposed in the through-holes 130b. In this manner, as shown in FIG. 7C, the terminal electrodes 130 are formed.

As shown in FIGS. 8A and 8B, the collective substrate 101 is secured to the collective substrate rest 152 at a position with a spacing S, taking into account factors such as the dimensional tolerance of the collective substrate 101. In the above electroplating step, therefore, the collective substrate 101 may be misaligned relative to the plating system 150 within the range of the spacing S. As shown in FIG. 8B, such misalignment of the collective substrate 101 relative to the plating system 150 may result in a gap G between the lid member 120 and the gasket 155 somewhere in the periphery of the lid member 120.

The contact area between the lid member 120 and the gasket 155 is usually minimized to maximize the effective or non-defective chip area of the collective substrate 101 without blocking the through-holes 130b with the gasket 155. Thus, only a slight misalignment may result in the gap G.

In the collective substrate 101 fabricated by WLP, as shown in FIGS. 7B and 7C, the power supply lines 104 are exposed in the hollow spaces surrounded by the collective substrate 101 and the lid member 120, with the support members 111 located therebetween. If the plating solution 153 spills over through the gap G in the above electroplating step, as shown in FIG. 8B, the plating solution 153 may enter the hollow spaces surrounded by the collective substrate 101 and the lid member 120 through the side surfaces of the support members 111. As shown in FIG. 8B, if the power supply lines 104 are in contact with the cathode 156 at any position when the plating solution 153 enter the hollow spaces, a current may flow through the entire power supply lines 104 and grow a coating thereon. In this case, to cut the collective substrate 101 to the desired chip size using a dicing blade along the power supply lines 104 on which the coating is grown after electroplating, not only the power supply lines 104 but also the coating grown thereon and containing a metal such as nickel relatively hard, need to be cut together. This may degrade the dicing properties. In addition, coating debris generated by dicing may short the pad electrodes 103.

### SUMMARY OF THE INVENTION

Accordingly, preferred embodiments of the present invention provide a method for manufacturing acoustic wave devices that prevents growth of a coating on power supply lines formed along the boundaries between chip regions when terminal electrodes are formed in an electroplating step and thus prevents degradation in dicing properties and a short between pad electrodes.

According to a preferred embodiment of the present invention, a method for manufacturing acoustic wave devices includes a first step of providing a piezoelectric collective substrate, to be divided into chip substrates, including a plurality of chip regions; a second step of forming an IDT electrode in each of the chip regions on a main surface of the collective substrate; a third step of forming pad electrodes electrically connected to the IDT electrode in each of the chip regions on the main surface of the collective substrate; a fourth step of forming power supply lines electrically connected to the pad electrodes along at least a portion of boundaries between the adjacent chip regions on the main surface of the collective substrate; a fifth step of providing substantially frame-shaped first support members spaced apart from each other on the main surface of the collective substrate, each having a first opening in which the IDT electrode is located and having or not having first through-holes formed in a region in which the pad electrodes are formed; a sixth step of providing second support members outside the first support members on the main surface of the collective substrate; a seventh step of providing a lid member on top surfaces of the first support members so as to seal the first openings, the lid member having or not having second through-holes formed at positions overlapping the first through-holes formed or not formed in plan view; an eighth step of forming the first through-holes in the first support members if the first through-holes are not formed or forming the second through-holes in the lid member if the second through-holes are not formed; a ninth step of forming terminal electrodes by supplying current to the pad electrodes through the power supply lines to precipitate a metal from a plating solution in the first through-holes and the second through-holes; and a tenth step of dividing the collective substrate into a plurality of chip substrates by cutting the lid member, the second support members, the power supply lines, and the collective substrate along the boundaries using a dicing blade. In the seventh step, the collective substrate, the first support members, the second support members, and the lid member form enclosed spaces in which the power supply lines are located to prevent the plating solution from coming into contact with the power supply lines in the ninth step.

The method described above prevents growth of a coating on the power supply lines in the electroplating step and thus prevents degradation in dicing properties and a short between the pad electrodes.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 illustrates a step of a method for manufacturing acoustic wave devices 100 according to a preferred embodiment of the present invention.

FIG. 2A is an enlarged view of a region F1 in FIG. 1, and FIG. 2B is a sectional view taken along line I-I in FIG. 2A.

FIGS. 3A and 3B illustrate a step, following the step shown in FIGS. 2A and 2B, of the method for manufacturing acoustic wave devices 100 according to a preferred embodiment of the present invention, where FIG. 3A is an enlarged view of the region F1 in FIG. 1, and FIG. 3B is a sectional view taken along line I-I in FIG. 3A.

FIGS. 4A and 4B illustrate a step, following the step shown in FIGS. 3A and 3B, of the method for manufacturing acoustic wave devices 100 according to a preferred embodiment of the present invention, where FIG. 4A is an enlarged view of the region F1 in FIG. 1, and FIG. 4B is a sectional view taken along line I-I in FIG. 4A.

FIGS. 5A and 5B illustrate an electroplating step, following the step shown in FIGS. 4A and 4B, of the method for manufacturing acoustic wave devices 100 according to a preferred embodiment of the present invention, where FIG. 5A is a sectional view illustrating the electroplating step, without IDT electrodes 2, pad electrodes 3, power supply lines 4, first through-holes 11b formed in first support members 11, second support members 12, and second through-holes 20b formed in a lid member 20, and FIG. 5B is an enlarged view of a region F2 in the electroplating step in FIG. 5A.

FIGS. 6A and 6B illustrate a step, following the step shown in FIGS. 5A and 5B, of the method for manufacturing acoustic wave devices 100 according to a preferred embodiment of the present invention, where FIG. 6A is an enlarged view of the region F1 in FIG. 1, and FIG. 6B is a sectional view taken along line I-I in FIG. 6A.

FIG. 7A is a plan view of a collective substrate 101 after wiring lines are formed and are sealed with resin in WLP and before the collective substrate 1 is cut to the chip size in a method for manufacturing acoustic wave devices in the related art, FIG. 7B is an enlarged view of a region F3 in FIG. 7A, and FIG. 7C is a sectional view taken along line I-I in FIG. 7B.

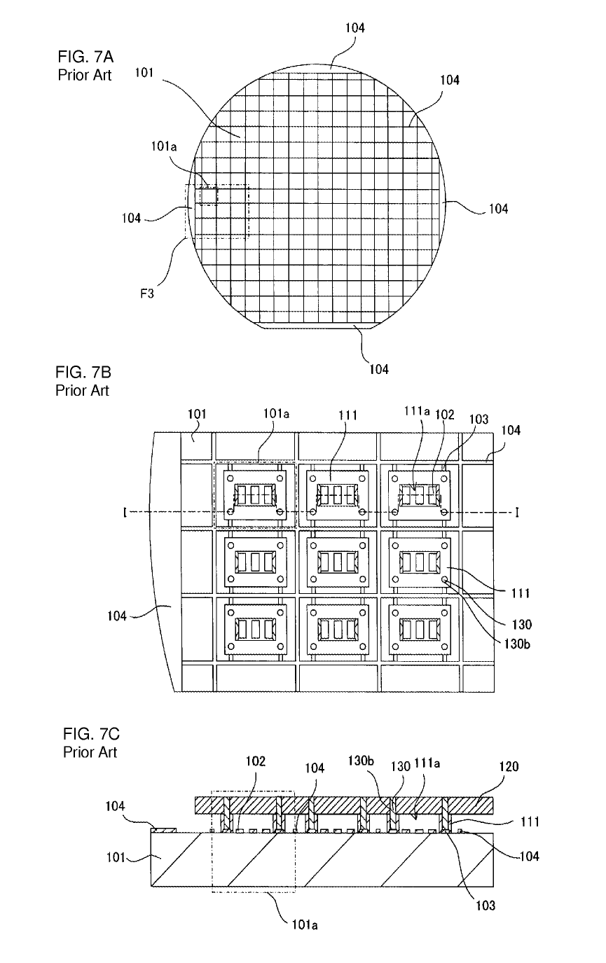

FIG. 8A is a sectional view of a cup plating system 150 used in the method for manufacturing acoustic wave devices in the related art, and FIG. 8B is an enlarged view of a region F4 in FIG. 8A.

### DETAILED DESCRIPTION OF THE PREFERRED EMBODIMENTS

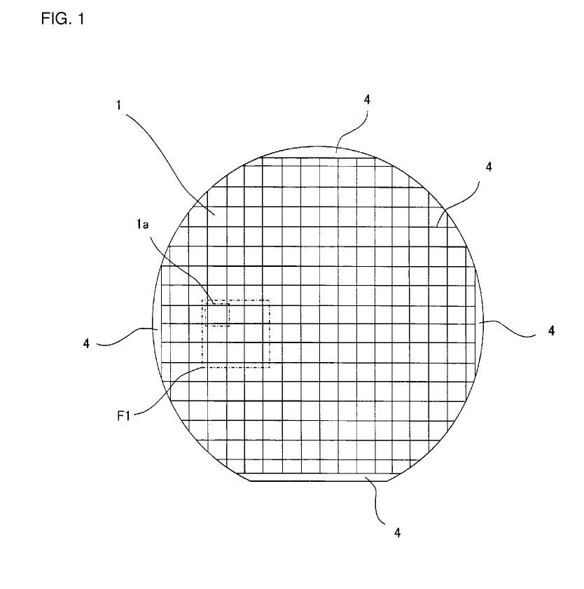

A method for manufacturing acoustic wave devices 100 according to a preferred embodiment of the present invention will now be described with reference to FIGS. 1 to 6B.

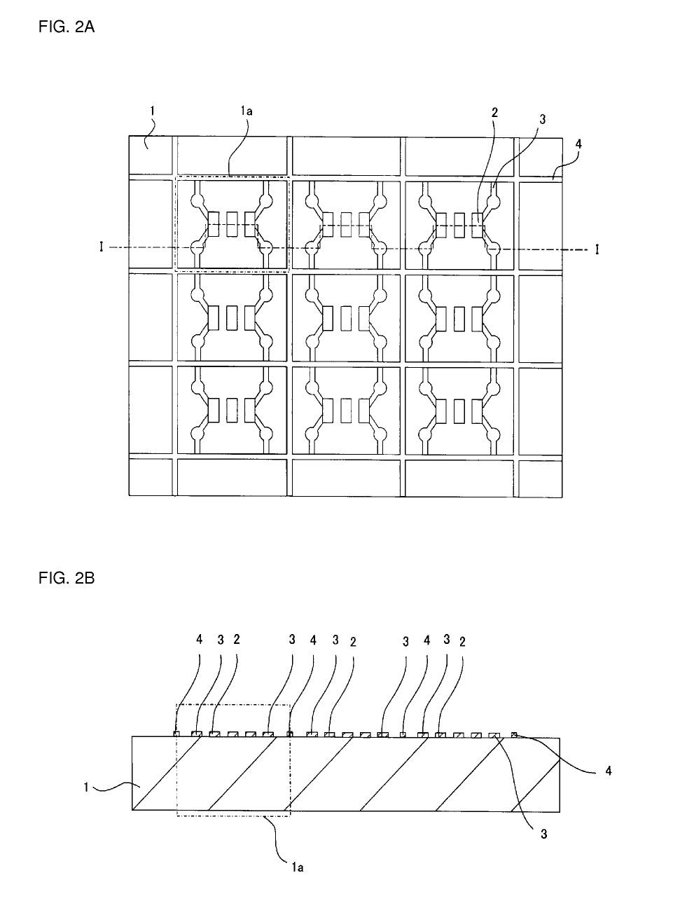

A substantially wafer-shaped piezoelectric collective substrate 1 is provided first. The collective substrate 1, which is to be divided into chip substrates, includes a plurality of chip regions 1a. As shown in FIGS. 1, 2A, and 2B, IDT electrodes 2, pad electrodes 3, and power supply lines 4 are formed in the chip regions 1a on the main surface of the collective substrate 1. The IDT electrodes 2 are made of, for example, platinum or aluminum-copper alloy.

Specifically, a metal layer is first deposited to a thickness of about 1 μm, for example, on the main surface of the collective substrate 1 by a thin-film deposition process such as sputtering, evaporation, or chemical vapor deposition (CVD), for example. The collective substrate 1 is made of a piezoelectric material such as lithium tantalate single crystal, quartz crystal, or ZnO. The metal layer is made of, for example, platinum or aluminum-copper alloy.

The metal layer is then patterned, for example, by photolithography using a reduction projection exposure system (stepper) and a reactive ion etching (RIE) system.

As shown in FIGS. 2A and 2B, the metal layer is patterned into the IDT electrodes 2, the pad electrodes 3, and the power supply lines 4. Each IDT electrode 2 is formed in the center or approximate center of one of the chip regions 1a on the main surface of the collective substrate 1. Each IDT electrode 2 is surrounded by a total of four pad electrodes 3 electrically connected to the IDT electrode 2. The power supply lines 4 are formed along the boundaries between the chip regions 1a and are electrically connected to the pad electrodes 3. As shown in FIG. 1, four additional power supply lines 4 are formed in the periphery of the collective substrate 1. These power supply lines 4 are electrically connected to the power supply lines 4 formed along the boundaries and are used later in an electroplating step.

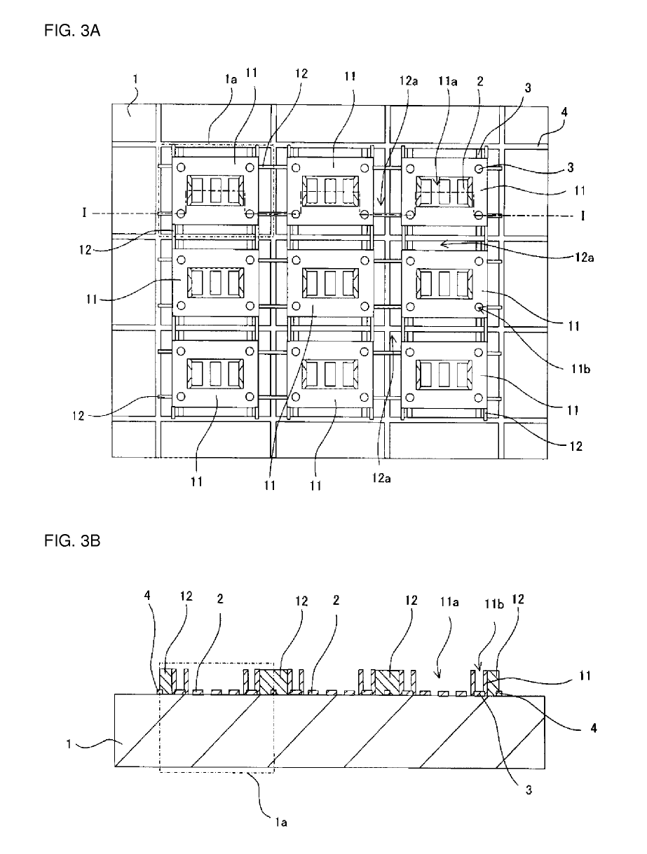

As shown in FIGS. 3A and 3B, substantially frame-shaped first support members 11 are then formed on the main surface of the collective substrate 1. The first support members 11 are spaced apart from each other and are made of a resin such as polyimide. Each first support member 11 has a first opening 11a in which one of the IDT electrodes 2 is located. Substantially linear second support members 12 are also formed on the main surface of the collective substrate 1. The second support members join the outer side surfaces of the adjacent first support members 11 to each other.

Specifically, for example, a thin film of a resin such as polyimide is first laminated by roll lamination. The thin film is then partially removed by photolithography or other techniques to form the first openings 11a, which form the vibration spaces for the IDT electrodes 2. Similarly, the thin film is partially removed to form first through-holes 11b in substantially frame-shaped regions in which the pad electrodes 3 are formed. The first through-holes 11b preferably have a diameter of, for example, about 100 μm.

At the same time as the formation of the first support members 11, the thin film is removed from near the boundaries between the chip regions 1a to form the substantially linear second support members 12 on the main surface of the collective substrate 1. The second support members 12 join the outer side surfaces of the adjacent first support members 11 to each other. Specifically, as shown in FIG. 3A, the second support members 12 join the long sides of the adjacent first support members 11 to each other and join the short sides of the adjacent first support members 11 to each other.

As shown in FIG. 3A, the outer side surfaces of the first support members 11 and the outer side surfaces of the second support members 12 form second openings 12a in which the power supply lines 4 are located. Thus, the second support members 12 preferably are formed over the entire collective substrate 1 so that the power supply lines 4 on the main surface of the collective substrate 1 are enclosed in the second openings 12a.

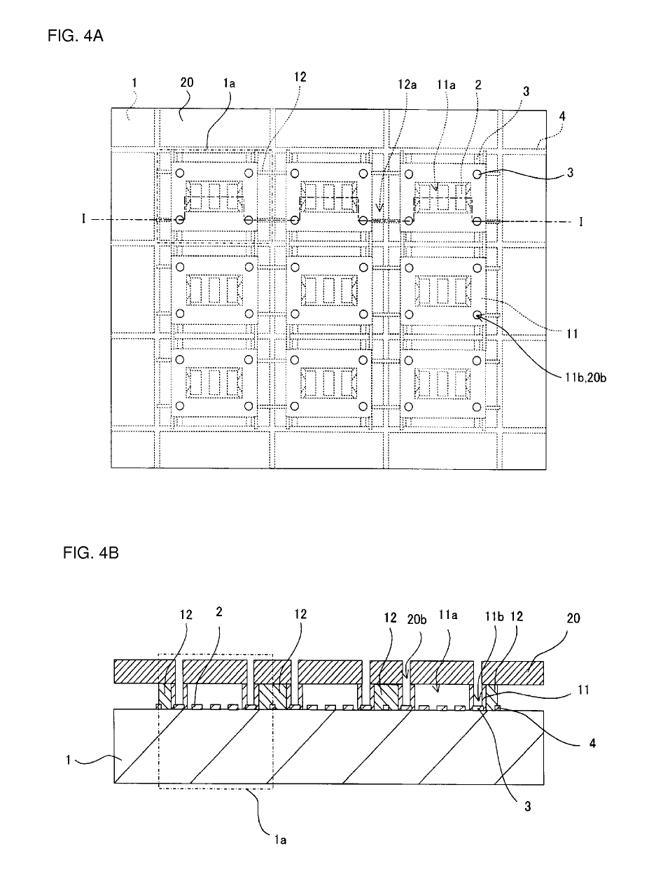

As shown in FIGS. 4A and 4B, a lid member 20 preferably having a height of several tens of micrometers is then formed on the top surfaces of the first support members 11 and the second support members 12. Specifically, a thin film of a resin such as polyimide is laminated by roll lamination to form the lid member 20. As a result, the thin film blocks the first openings 11a, which form the vibration spaces for the IDT electrodes 2. The thin film is also provided on the second support members 12 to block the second openings 12a. Thus, the collective substrate 1, the first support members 11, the second support members 12, and the lid member 20 form enclosed spaces. As a result, the power supply lines 4 are located in the enclosed spaces.

The lid member 20 is then removed from the positions overlapping the first through-holes 11b in plan view by photolithography or other techniques to form second through-holes 20b. The second through-holes 20b preferably have a diameter of, for example, about 100 μm.

The collective substrate 1 is then heated in an oven in a N2 atmosphere to cure the first support members 11, the second support members 12, and the lid member 20.

Terminal electrodes 30 are then formed in the first through-holes 11b and the second through-holes 20b by electroplating. The terminal electrodes 30 are electrically connected to the pad electrodes 3.

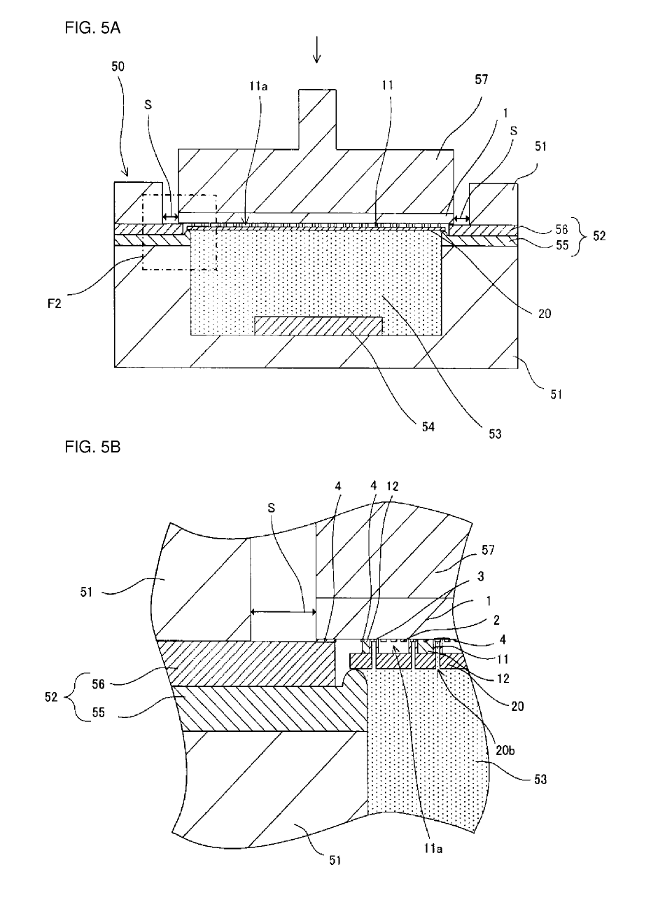

Electroplating is performed using a cup plating system 50 shown in FIG. 5A. This plating system 50 includes a plating cell 51 filled with a plating solution 53 containing nickel and a collective substrate rest 52 disposed around a top opening of the plating cell 51. An anode (positive electrode) 54, serving as one of the electroplating electrodes, is disposed in the plating cell 51. The collective substrate rest 52 preferably includes a gasket 55 having a protrusion extending along the inner edge thereof and a cathode (negative electrode) 56 defining and serving as the other electroplating electrode.

Electroplating using the cup plating system 50 will now be described step by step.

As shown in FIGS. 5A and 5B, the collective substrate 1 on which the lid member 20 is formed is first mounted on the plating system 50. Specifically, the collective substrate 1 is placed on the collective substrate rest 52, with the lid member 20 facing downward, such that the periphery of the lid member 20 is located on the gasket 55 and that the power supply lines 4 on the collective substrate 1 are located on the cathode 56.

The collective substrate 1 is then secured to the plating cell 51 by pressing the collective substrate 1 against the collective substrate rest 52 with a pressing member 57 to ensure that the lid member 20 is in contact with the gasket 55 and that the cathode 56 is in contact with the four power supply lines 4, shown in FIG. 1, formed in the periphery of the collective substrate 1. As a result, the collective substrate 1 comes into contact with the plating solution 53 in the plating cell 51.

The anode 54 and the cathode 56 are then supplied with current, which allows a coating to grow on the surfaces of the pad electrodes 3 in contact with the plating solution 53 in the first through-holes 11b and the second through-holes 20b. As a result, metallic nickel precipitates from the plating solution 53 in the first through-holes 11b and the second through-holes 20b to form a nickel layer.

A plating solution 53 containing gold is then used in a similar cup plating system 50 to grow a gold layer on the nickel layer. By this plating step, the terminal electrodes 30 are formed, which preferably include two layers, i.e., the nickel and gold layers.

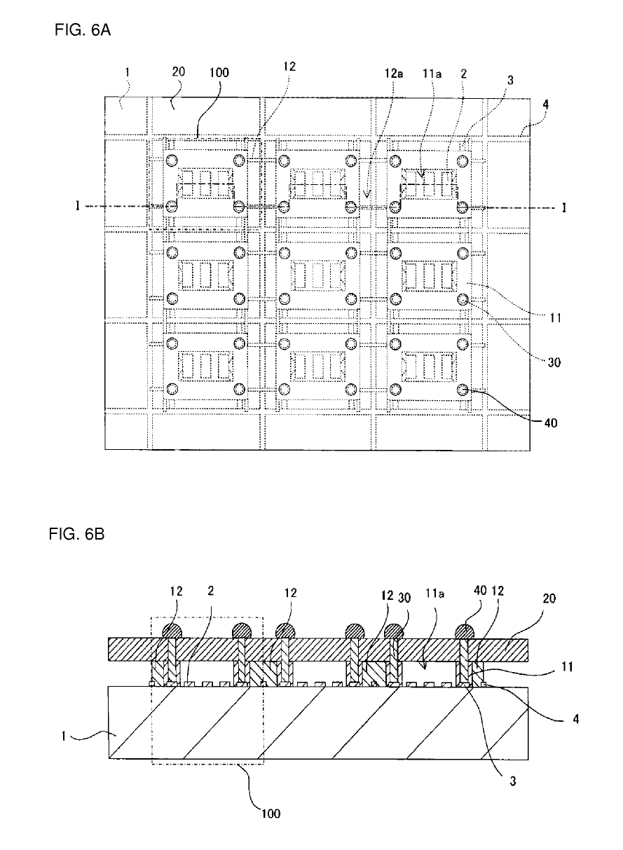

As shown in FIGS. 6A and 6B, a solder paste is then printed on and around the top surfaces of the terminal electrodes 30 using a metal mask and is reflowed and cleaned with flux to form solder balls 40.

Finally, the lid member 20, the second support members 12, the power supply lines 4, and the collective substrate 1 are cut using a dicing blade along the boundaries between the chip regions 1a of the collective substrate 1 while removing the power supply lines 4 to obtain separate acoustic wave devices 100. Thus, the method for manufacturing the acoustic wave devices 100 according to this preferred embodiment is completed.

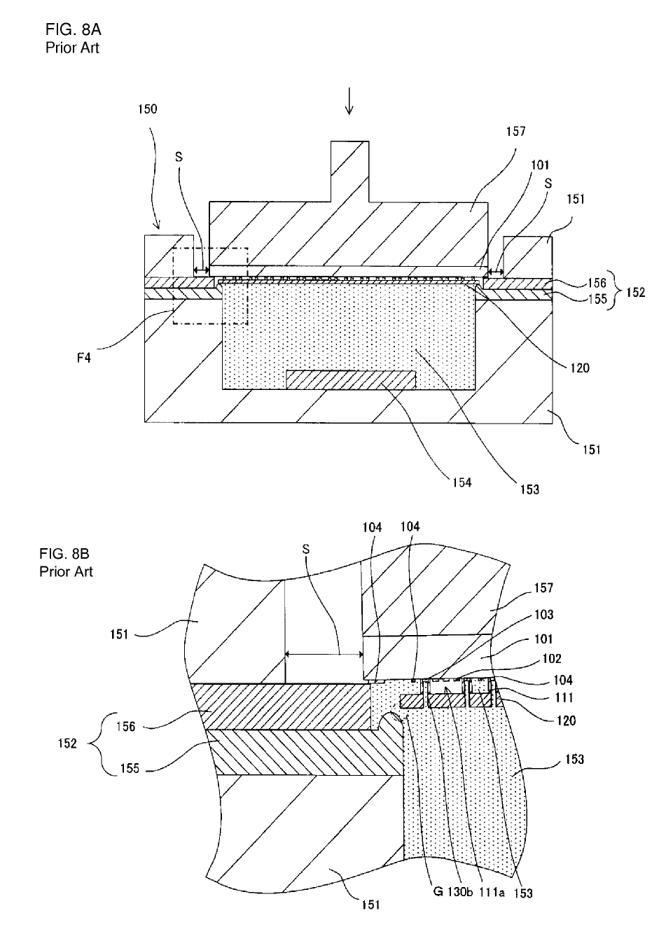

In the electroplating step, the plating solution 53 normally does not leak between the lid member 20 and the collective substrate rest 52 because the entire periphery of the lid member 20 is in contact with the gasket 55. However, as described with reference to FIG. 8B, a gap may be formed between the gasket 55 and the lid member 20 during electroplating, for example, due to misalignment of the collective substrate 1 when it is placed on the plating system 50.

In this preferred embodiment, even if a gap is formed between the gasket 55 and the lid member 20 in the electroplating step, the plating solution 53 does not come into contact with the power supply lines 4 because they are sealed in the enclosed spaces formed by the collective substrate 1, the first support members 11, the second support members 12, and the lid member 20. As a result, even if the plating solution 53 flows through the gap, no coating grows on the power supply lines 4 when they are supplied with current through the cathode 56 in contact therewith. Thus, this method prevents growth of a coating on the power supply lines 4 along the boundaries and thus prevents degradation in dicing properties. In addition, this method prevents a short between the pad electrodes 103 of the acoustic wave devices 100 due to coating debris generated when the collective substrate 1 is divided into chip substrates.

In this preferred embodiment, multiple second support members 12 are formed between the adjacent first support members 11. This more reliably prevents the plating solution 53 from flowing onto the power supply lines 4.

To grow coatings of different metals, such as nickel and gold, the collective substrate 1 needs to be secured to the plating system 50 multiple times. In this preferred embodiment, however, no coating grows on the power supply lines 4 irrespective of the number of times the collective substrate 1 is secured to the plating system 50.

In this preferred embodiment, the second support members 12 are formed in each of the chip regions 1a to prevent entry of the plating solution 53. This eliminates the need to redesign the shape of the second support members 12 depending on the shape and size of the collective substrate 1.

In this preferred embodiment, the first support members 11 and the second support members 12 preferably are formed in the same step. This eliminates the need to add a separate step of forming the second support members 12 and thus reduces manufacturing costs.

The present invention is not limited to this preferred embodiment. Various modifications are possible within the scope of the present invention.

For example, in the above-described preferred embodiment, the second support members 12 are preferably formed on the main surface of the collective substrate 1 and join the outer side surfaces of the adjacent first support members 11 to each other; in addition to the second support members 12, a substantially frame-shaped third support member surrounding all chip regions 1a preferably is formed along the periphery of the collective substrate 1. This more reliably prevents growth of a coating on the power supply lines 4 even if a gap is formed between the gasket 55 and the lid member 20 and the plating solution 53 flows through the gap from the sides of the collective substrate 1.

In the above-described preferred embodiment, two substantially linear second support members 12 are preferably formed on each outer side surface of each first support member 11 and join the outer side surfaces of the adjacent first support members 11 to each other. However, the second support members 12 may be provided in any number and shape if they can prevent entry of the plating solution 53. For example, the second support members 12 may be provided so as to surround a plurality of chip regions positioned at the center of the main surface of the collective substrate 1. In one specific example, the second support members 12 are preferably joined to the outer side surface of the first support members 11 adjacent to each other arranged along the outer periphery of the main surface of the collective substrate 11. Inside of a sealed space formed by the second supporting members 12, the first supporting members 11, the collective substrate 1 and the lid member 20, a plurality of chip regions are included.

In the above-described preferred embodiment, the first through-holes 11b are preferably formed when the first support members 11 are formed, and the second through-holes 20b are formed when the lid member 20 is formed; however, the first through-holes 11b and the second through-holes 20b are not necessarily formed when the first support members 11 and the second support members 12 are formed, respectively. For example, the first through-holes 11b and the second through-holes 20b may be simultaneously formed by laser irradiation or other techniques after the lid member 20 is formed on the first support members 11.

Alternatively, the first through-holes 11b may be formed when the first support members 11 are formed, and after the lid member 20 is formed on the first support members 11, the second through-holes 20b may be formed in the lid member 20 at the positions overlapping the first through-holes 11b in plan view by laser irradiation or other techniques.

Alternatively, the second through-holes 20b may be formed when the lid member 20 is formed, and the first through-holes 11b may be formed in the first support members 11 by laser irradiation through the second through-holes 20b or other techniques.

Although the terminal electrodes 30 in the above-described preferred embodiment are formed preferably by electroplating using the cup plating system 50, electroplating may be performed in other manners, such as using a rack plating system.

Although the plating solution 53 used for electroplating in the above-described preferred embodiment preferably contains nickel or gold, it may contain other materials.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A method for manufacturing acoustic wave devices, comprising:
a first step of providing a piezoelectric collective substrate, to be divided into chip substrates, including a plurality of chip regions;
a second step of forming an interdigital transducer electrode in each of the chip regions on a main surface of the collective substrate;
a third step of forming pad electrodes electrically connected to the IDT electrode in each of the chip regions on the main surface of the collective substrate;
a fourth step of forming power supply lines electrically connected to the pad electrodes along at least a portion of boundaries between the adjacent chip regions on the main surface of the collective substrate;
a fifth step of providing substantially frame-shaped first support members spaced apart from each other on the main surface of the collective substrate, each including a first opening in which the IDT electrode is located and including or not having first through-holes formed in a region in which the pad electrodes are formed;
a sixth step of providing second support members outside the first support members on the main surface of the collective substrate;
a seventh step of providing a lid member on top surfaces of the first support members so as to seal the first openings, the lid member having or not having second through-holes formed at positions overlapping the first through-holes formed or not formed in plan view;
an eighth step of forming the first through-holes in the first support members if the first through-holes are not formed or forming the second through-holes in the lid member if the second through-holes are not formed;
a ninth step of forming terminal electrodes by supplying current to the pad electrodes through the power supply lines to precipitate a metal from a plating solution in the first through-holes and the second through-holes; and
a tenth step of dividing the collective substrate into a plurality of chip substrates by cutting the lid member, the second support members, the power supply lines, and the collective substrate along the boundaries using a dicing blade; wherein
the collective substrate, the first support members, the second support members, and the lid member form enclosed spaces in which the power supply lines are located in the seventh step to prevent the plating solution from coming into contact with the power supply lines in the ninth step.

2. The method for manufacturing acoustic wave devices according to claim 1, wherein the second support members provided in the sixth step join outer side surfaces of the adjacent first support members to each other.

3. The method for manufacturing acoustic wave devices according to claim 1, wherein the power supply lines formed along the boundaries surrounding at least two adjacent chip regions are located in the enclosed spaces in the seventh step.

4. The method for manufacturing acoustic wave devices according to claim 1, wherein the interdigital transducer electrode is formed in a center or an approximate center of the respective chip region.

5. The method for manufacturing acoustic wave devices according to claim 1, wherein the interdigital electrode is surrounded by four of the pad electrodes electrically connected to the interdigital transducer electrode.

6. The method for manufacturing acoustic wave devices according to claim 1, wherein four additional power supply lines are formed in a periphery of the collective substrate.

7. The method for manufacturing acoustic wave devices according to claim 1, wherein the substantially frame-shaped first support members are formed of resin.

8. The method for manufacturing acoustic wave devices according to claim 1, wherein the second support members are formed of resin.

9. The method for manufacturing acoustic wave devices according to claim 1, wherein second openings are formed by outer side surfaces of the first support members and outer side surfaces of the second support members such that the power supply lines are located in the second openings.

10. The method for manufacturing acoustic wave devices according to claim 1, further comprising the step of heating the collective substrate to cure the first support members, the second support members and the lid member.

11. The method for manufacturing acoustic wave devices according to claim 1, wherein the ninth step of forming terminal electrodes is performed using a cup plating system.

12. The method for manufacturing acoustic wave devices according to claim 1, wherein each of the terminal electrodes includes a first metal layer and a second metal layer.

13. The method for manufacturing acoustic wave devices according to claim 12, wherein the first metal layer is formed of nickel and the second metal layer is formed of gold.

14. The method for manufacturing acoustic wave devices according to claim 1, wherein a plurality of the second support members are formed between adjacent pairs of the first support members.

15. The method for manufacturing acoustic wave devices according to claim 1, wherein the second support members are formed in each of the chip regions.

16. The method for manufacturing acoustic wave devices according to claim 1, wherein the first support members and the second support members are formed at the same time.

17. The method for manufacturing acoustic wave devices according to claim 1, further comprising forming a substantially frame-shaped third support member surrounding all of the chip regions along a periphery of the collective substrate.

18. The method for manufacturing acoustic wave devices according to claim 1, wherein the first through-holes are formed when the first support members are formed, and the second through-holes are formed when the lid member is formed.

19. The method for manufacturing acoustic wave devices according to claim 1, wherein the first through-holes and the second through-holes are formed simultaneously.

20. The method for manufacturing acoustic wave devices according to claim 1, wherein the first through-holes are formed when the first support members are formed and after the lid member is formed on the first support members, and the second through-holes are formed in the lid member at positions overlapping the first through-holes in plan view.
